(19) United States
(12) Patent Application Publication
(10) Pub. No.: US 2018/0337083 A1
(43) Pub. Date: Nov. 22, 2018

(54) METHOD OF PROCESSING SUBSTRATE

(71) Applicant: SAMSUNG ELECTRONICS CO., LTD., Suwon-si (KR)

(72) Inventors: Satoshi Inada, Asan-si (KR); Je-kook Lyu, Asan-si (KR); Yoshihisa Saimoto, Asan-si (KR); Yoon-seok Song, Anyang-si (KR); Kyung-hak Lee, Yongin-si (KR); Ki-hyun Jung, Cheonan-si (KR)

(21) Appl. No.: 15/871,620

(22) Filed: Jan. 15, 2018

(30) Foreign Application Priority Data
May 17, 2017 (KR) 10-2017-0061054

(51) Int. Cl. H01L 21/683

(52) U.S. Cl. CPC H01L 21/6836; H01L 24/14

(57) ABSTRACT

A method of processing a substrate includes attaching a first surface of a planarization film to a processing target substrate, disposing an electrostatic carrier onto a second surface opposite the first surface of the planarization film, fixing the processing target substrate to the electrostatic carrier by supplying power to the electrostatic carrier, and performing processing on the processing target substrate.

### CROSS-REFERENCE TO RELATED APPLICATION

This application claims the benefit of Korean Patent Application No. 10-2017-0061054, filed on May 17, 2017, in the Korean Intellectual Property Office, the disclosure of which is incorporated by reference herein in its entirety.

### TECHNICAL FIELD

The inventive concept relates to a method of processing a substrate, and more particularly, to a method of processing a substrate quickly at room temperature without imparting thermal/mechanical stress to the substrate.

### DISCUSSION OF THE RELATED ART

A wafer is temporarily supported during three-dimensional (3D) or two and a half dimensional (2.5D) mounting by using a through-silicon via (TSV). Various methods for temporarily supporting a wafer have been proposed, but each method has insufficiencies.

### SUMMARY

The inventive concept provides a method of processing a substrate.

According to an aspect of the inventive concept, a method for processing a substrate includes attaching a first surface of a planarization film to a processing target substrate, disposing an electrostatic carrier onto a second surface opposite the first surface of the planarization film, fixing the processing target substrate to the electrostatic carrier by supplying power to the electrostatic carrier, and performing processing on the processing target substrate. Here, the planarization film includes a base film, an adhesive layer formed on the base film, and an unevenness covering layer formed on the adhesive layer.

According to an aspect of the inventive concept, a method for processing a substrate includes forming an unevenness covering layer, an adhesive layer and a base film layer on a processing target substrate, curing the unevenness covering layer and the adhesive layer, disposing an electrostatic carrier onto the base film layer, fixing the processing target substrate to the electrostatic carrier by supplying power to the electrostatic carrier, and processing the processing target substrate.

According to an aspect of the inventive concept, a method for thinning a substrate includes attaching a first surface of a planarization film to a thinning target substrate, attaching a carrier substrate to a second surface opposite the first surface of the planarization film, performing thinning on the thinning target substrate, and removing the carrier substrate. Here, the planarization film includes a base film, an adhesive layer formed on the base film, and an unevenness covering layer formed on the adhesive layer.

### BRIEF DESCRIPTION OF THE DRAWINGS

Exemplary embodiments of the inventive concept will be more clearly understood from the following detailed description taken in conjunction with the accompanying drawings in which:

FIG. 1 illustrates a flowchart showing a method of processing a substrate, according to an exemplary embodiment of the inventive concept.

FIGS. 2A to 2H illustrate cross-sectional side views of the substrate according to steps of the method of processing the substrate.

FIG. 3 illustrates a cross-sectional side view showing a method of removing a base film from a processing target substrate, according to an exemplary embodiment of the inventive concept.

FIG. 4 illustrates a flowchart showing a method of processing a substrate, according to an exemplary embodiment of the inventive concept.

FIGS. 5A to 5D illustrate cross-sectional side views of a substrate according to some steps of the method of processing the substrate.

FIG. 6 illustrates a conceptual view showing a cross-section of a planarization film according to an exemplary embodiment of the inventive concept.

FIG. 7 illustrates a cross-sectional side view of a semiconductor package manufactured using a processed substrate, according to an exemplary embodiment of the inventive concept.

### DETAILED DESCRIPTION OF THE EMBODIMENTS

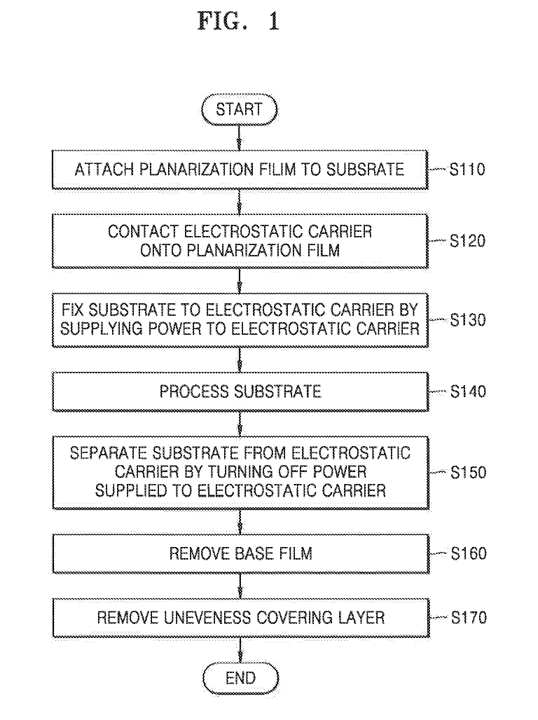

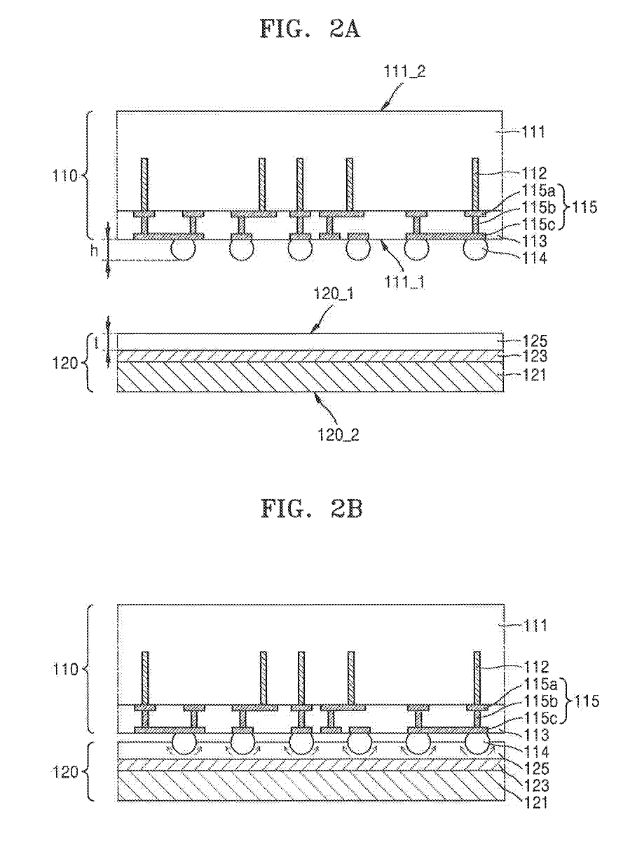

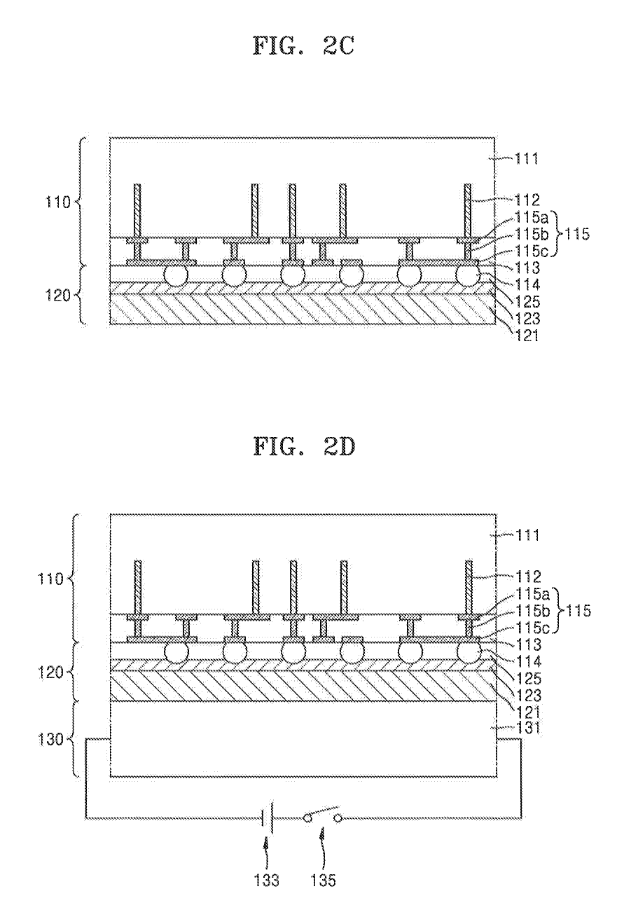

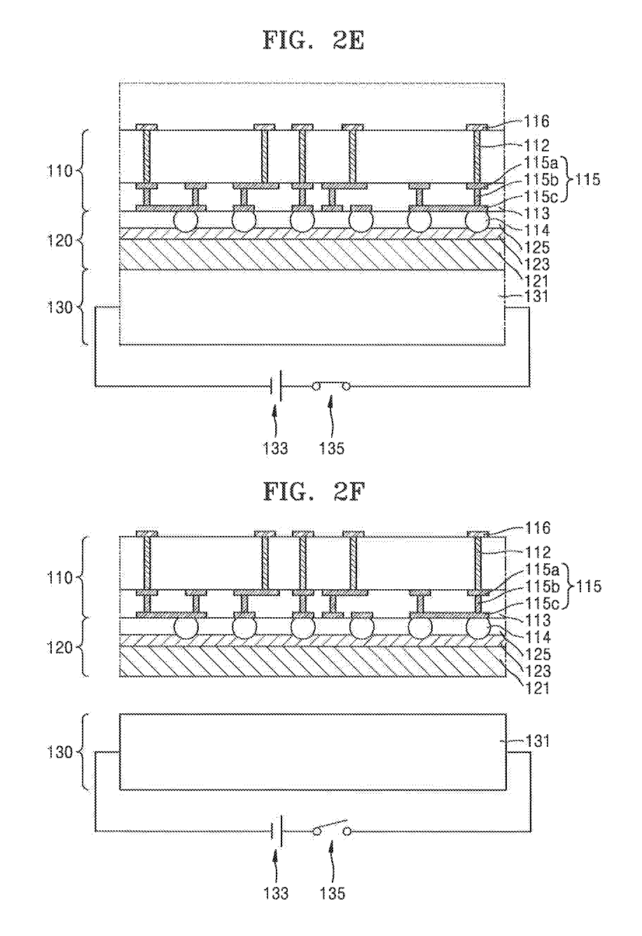

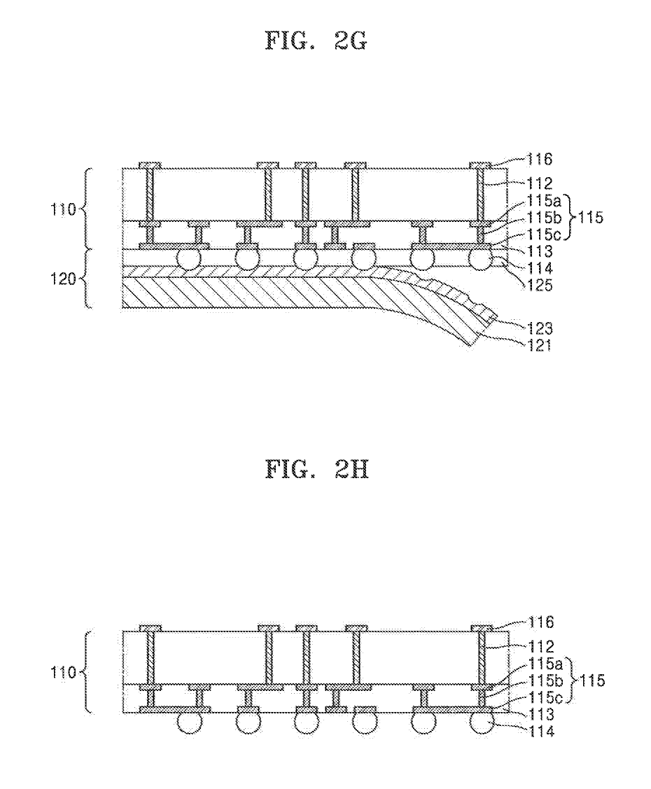

FIG. 1 illustrates a flowchart showing a method of processing a substrate, according to an exemplary embodiment of the inventive concept. FIGS. 2A to 2H illustrate cross-sectional side views of the substrate according to steps of the method of processing the substrate.

Referring to FIG. 1, and FIGS. 2A to 2C, a planarization film 120 may be attached onto a processing target substrate 110 to be processed (S110).

The processing target substrate 110 may include a semiconductor substrate 111 and a wiring layer 113 formed on one side of main surfaces of the semiconductor substrate 111. Furthermore, the processing target substrate 110 may have an active surface 111_1 and an opposite surface 111_2 opposite the active surface 111_1 as two main surfaces.

A plurality of semiconductor devices may be formed on the active surface 111_1 or in an inner portion near the active surface 111_1. In addition, penetration electrodes 112 such as through silicon vias (TSVs) may be provided in an inner portion of the processing target substrate 110. The penetration electrodes 112 may be electrically connected to the semiconductor devices. The penetration electrodes 112 may extend towards the opposite surface 111_2 from the active surface 111_1 or a surface of the semiconductor substrate 111 close to the active surface 111_1.

A penetration electrode 112 may be electrically connected to a conductive bump 114 through the wires 115 formed inside the wiring layer 113. The wires 115 may include a first conductive body 115a directly contacting the penetration electrode 112, a second conductive body 115c directly contacting the conductive bump 114, and a vertical conductive body 115b electrically connecting the first conductive body 115a and the second conductive body 115c.

The constitution of the semiconductor substrate 111 may be based on a semiconductor wafer. For example, the semiconductor substrate 111 may include a Group IV material or a Group III-V compound. Particularly, the semiconductor substrate 111 may include Si, SiC, SiGe, SiGeC, Ge alloys, GaAs, InAs, TnP, other Group III-V or Group II-VI compound semiconductors, or an organic semiconductor substrate. Also, in terms of a formation method, the semiconductor substrate 111 may be formed from a monocrystalline wafer such as a silicon single crystalline wafer. However, the semiconductor substrate 111 is not limited to the monocrystalline wafer, and may be formed from various wafers including an epitaxial wafer, a polished wafer, an annealed wafer, and a silicon-on-insulator (SOI) wafer. Here, the epitaxial wafer means a wafer in which a crystalline material is grown on a monocrystalline substrate.

A semiconductor device may be formed inside an interlayer insulating layer on one surface of the semiconductor substrate 111. The semiconductor device may include, for example, an active device such as a transistor or a diode, and/or a passive device such as a capacitor or a resistor. Depending on a configuration, the semiconductor device may include an image sensor such as a large-scale integration (LSI) system, a logic circuit, and a CMOS imaging sensor (CIS). In addition, the semiconductor device may include a memory device such as a flash memory, a dynamic random-access memory (DRAM), a static random-access memory (SRAM), an electrically erasable programmable read-only memory (EEPROM), a phase change random-access memory (PRAM), an magnetoresistive random-access memory (MRAM), a resistive random-access memory (ReRAM), a high bandwidth memory (HBM), a hybrid memory cubic (HMC), a microelectromechanical system (MEMS) device, and the like.

As described above, the first conductive body 115a, the second conductive body 115c and the vertical conductive body 115b are provided inside the wiring layer 113, and these conductive bodies may be insulated by an insulator as necessary. The insulator may have a stacked structure in which various layers formed of a material such as an oxide, a nitride, a low-k material, a high-k material, or a combination thereof are stacked. Although the insulator is illustrated as being formed as a single layer in FIG. 2A, one of ordinary skill in the art would understand that it may be formed as a multi-layered structure and that a conductive body may be interposed between the multiple layers of the insulator.

The wiring layer 113 may include aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr), and/or a conductive metal nitride such as a titanium nitride, a tantalum nitride, and a tungsten nitride.

Configurations of and connections between the conductive bodies shown in FIGS. 2A to 2H are exemplary, and the inventive concept is not limited thereto.

The planarization film 120 may include a base film 121, an adhesive layer 123 formed on the base film 121, and an unevenness covering layer 125 formed on the adhesive layer 123.

The base film 121 may be formed of a material having high heat resistance and electrical conductivity. For example, the base film 121 may include any of doped polyimide, polyethylene terephthalate (PET), polyethylene, polypropylene, polyethylene-2,6-naphthalate, polypropylene terephthalate, polyamide-imide, polyethersulfone, polyether ether ketone, polycarbonate, polyarylate, cellulose propionate, polyvinyl chloride, polyvinylidene chloride, polyvinyl alcohol, polyether imide, polyphenylene sulfide, polyphenylene oxide, polystyrene, copper foil, and the like.

The adhesive layer 123 may be a silicone-based resin, for example, a polymerizable composition that may include a silicone monomer or oligomer and can be used for adhesion. In an exemplary embodiment, the adhesive layer 123 may have a polysiloxane structure. In an exemplary embodiment, the adhesive layer 123 may be a polysiloxane resin, a silicone-modified resin, a non-reactive modified silicone oil, a reactive modified silicone oil, or a straight silicone oil, but the inventive concept is not limited thereto.

The adhesive layer 123 may have a relatively high modulus of about 0.3 to about 1.0 MPa.

The unevenness covering layer 125 may include any thermoplastic resin or any thermosetting resin of which viscosity may be increased at a temperature of about 60° C. to about 200° C. while having heat resistance and being readily soluble in an organic solvent.

In an exemplary embodiment, the thermosetting resin may be an unreacted thermosetting resin. Thus, when its temperature is increased through heating, the viscosity thereof reduces such that it has fluidity at an initial stage, but if heat is continuously applied thereto, the resin may eventually be thermally cured, thereby leading to loss of fluidity.

The thermoplastic resin may include general use plastics such as acrylic, modified acrylic, low density polyethylene, high density polyethylene, ethylene-vinyl acetate copolymer, polyethylene terephthalate, polypropylene, modified polypropylene, polystyrene, acrylonitrile butadiene styrene copolymer, acrylonitrile-styrene copolymer, acetylcelluose, polyvinyl alcohol, polyvinyl chloride, polyvinylidene chloride and polylactic acid, engineering plastics such as polyamide, thermoplastic polyurethane, polyacetal, polycarbonate, ultrahigh molecular weight polyethylene, polybutylene terephthalate, modified polyphenylene ether, polysulfone (PSF), polyphenylene sulfide (PPS), polyethersulfone (PES), polyether ether ketone, polyarylate, polyether imide, polyamide-imide, liquid crystal polymer, polyamide 6T, polyamide 9T, polytetrafluoroethylene, polyvinylidene fluoride, polyester-imide and thermoplastic polyimide, and thermoplastic elastomers such as olefin-based elastomer, styrene-based elastomer, polyester-based elastomer, urethane-based elastomer, amide-based elastomer, vinyl chloride-based elastomer and hydrogen bonding-based elastomer.

The thermosetting resin is a resin that may be cured by heat and have electrical insulation properties. The thermosetting resin may include, for example, a bisphenol-type epoxy resin such as bisphenol A-type epoxy resin, bisphenol F-type epoxy resin, bisphenol S-type epoxy resin, bisphenol E-type epoxy resin, bisphenol M-type epoxy resin, bisphenol P-type epoxy resin and bisphenol Z-type epoxy resin, a novolac-type epoxy resin such as bisphenol A novolac-type epoxy resin, phenol novolac-type epoxy resin and cresol novolac epoxy resin, a novolac-type phenol resin such as biphenyl-type epoxy resin, biphenyl aralkyl-type epoxy resin, arylalkylene-type epoxy resin, tetra phenylol ethane-type epoxy resin, naphthalene-type epoxy resin, anthracene-type epoxy resin, phenoxy-type epoxy resin, dicyclo pentadiene-type epoxy resin, norbornene-type epoxy resin, adamantane-type epoxy resin, fluorene-type epoxy resin, glycidyl methacrylate copolymer epoxy resin, copolymer epoxy resin of cyclohexyl maleimide and glycidyl methacrylate, epoxy modified polybutadiene rubber derivative, carboxyl-terminated butadiene-acrylonitrile (CTBN) modified epoxy resin, trimethylol propane polyglycidyl ether, phenyl-1,3-di glycidyl ether, biphenyl-4,4′-di glycidyl ether, 1,6-hexanediol di glycidyl ether, diglycidyl ether of ethylene glycol or propylene glycol, sorbitol polyglycidyl ether, tris (2,3-epoxy propyl) isocyanurate, triglycidyl tris (2-hydroxyethyl) isocyanurate, phenolnovolac resin, cresol novolac resin and bisphenol A novolac resin, unmodified resol phenol resin, phenol resin, phenoxy resin, urea resin, and a resin containing a triazine ring such as melamine resin, unsaturated polyester resin, bismaleimide resin, dialyl phthalate resin, silicone resin, benzoxazine ring resin, norbornene resin, cyanate resin, isocyanate resin, urethane resin, benzocyclobutene resin, maleimide resin, bismaleimide-triazine resin, poly azomethine resin and polyimide resin. From among the aforementioned resins, epoxy resin or polyimide resin may be particularly used in that they have excellent reliability as an insulating layer.

For example, the unevenness covering layer 125 may be made of a material such as Adflema PA0101 commercially available from Namics Corporation.

The unevenness covering layer 125 may have a relatively low modulus of about 0.01 to 0.5 MPa.

A thickness t of the unevenness covering layer 125 may be about 60% to about 95% of a height h of the conductive bump 114.

If the thickness t of the unevenness covering layer 125 is small, the unevenness covering layer 125 may not fully fill a space between conductive bumps 114. In other words, there may be an empty space between the unevenness covering layer 125 and the conductive bump 114, or an area of contact between the conductive bump 114 and the adhesive layer 123 may be excessive. If the area of contact between the conductive bump 114 and the adhesive layer 123 is excessive, the conductive bump 114 may be damaged when the adhesive layer 123 is later peeled off from a side of the processing target substrate 110.

Otherwise, if the thickness t of the unevenness covering layer 125 is large, the conductive bump 114 may not contact the adhesive layer 123, or the unevenness covering layer 125 may protrude over a side surface of the processing target substrate 110. If the unevenness covering layer 125 protrudes over the side surface of the processing target substrate 110, horizontality of the processing target substrate 110 may not be maintained, and thus, some of the conductive bumps 114 may directly contact a carrier that will be described below.

As illustrated in FIG. 2A, the processing target substrate 110 and the planarization film 120 may be positioned such that the active surface 111_1 of the processing target substrate 110 faces towards a first surface 120_1 of the planarization film 120. In other words, a positional relationship between the processing target substrate 110 and the planarization film 120 may be determined so as to attach the active surface 111_1 of the processing target substrate 110 to the first surface 120_1, which is a free surface of the planarization film 120.

Then, as illustrated in FIG. 2B, the planarization film 120 contacts the processing target substrate 110 to be attached thereto, and the planarization film 120 is heated to provide a fluidity to the unevenness covering layer 125. To reduce viscosity of the unevenness covering layer 125, the planarization film 120 may be heated to a temperature of about 60° C. to about 200° C.

When the planarization film 120 is heated, viscosity of the unevenness covering layer 125 is reduced such that it gradually has fluidity. Even when the unevenness covering layer 125 is a thermosetting resin, viscosity may be reduced as its temperature increases in a state in which a crosslinking reaction has not yet begun.

When a viscosity of the unevenness covering layer 125 is low, the processing target substrate 110 and the planarization film 120 are pressed towards each other. The unevenness covering layer 125 having fluidity due to low viscosity may gradually fill a space between the conductive bumps 114. As illustrated in FIG. 2B, the unevenness covering layer 125 having fluidity flows around protruding conductive bump 114 to fill spaces between the protruding conductive bumps 114.

Referring to FIG. 2C, when the unevenness covering layer 125 fully fills the spaces between the conductive bumps 114, the conductive bump 114 may partly contact the adhesive layer 123 by passing through the unevenness covering layer 125. In other words, an end portion of the conductive bump 114 may, at least partly, contact the adhesive layer 123.

As described above, the adhesive layer 123 may have a modulus relatively greater than that of the unevenness covering layer 125. In this regard, the conductive bumps 114 may slightly deform or may not deform the adhesive layer 123 and contact the base film 121 by passing through the adhesive layer 123.

As illustrated in FIG. 2C, when the processing target substrate 110 and the planarization film 120 are pressed towards each other, the adhesive layer 123 and the unevenness covering layer 125 may be cured.

In an exemplary embodiment, the adhesive layer 123 and the unevenness covering layer 125 may be cured by heat or light. For example, the adhesive layer 123 and the unevenness covering layer 125 may be cured by being heated to a temperature of about 60° C. to about 200° C. In this case, thermal curing may be performed consecutively after heating to reduce viscosity of the unevenness covering layer 125.

In an exemplary embodiment, the adhesive layer 123 and the unevenness covering layer 125 may be irradiated with ultraviolet (UV) light so as to cure the adhesive layer 123 and the unevenness covering layer 125. An amount of the UV light may be in a range of about 1000 mJ/cm² to about 6000 mJ/cm², but the inventive concept is not limited thereto. Also, when the adhesive layer 123 and the unevenness covering layer 125 are photo-cured by irradiation of UV light thereto, the base film 121 may, at least partially, transmit a UV light. For example, the base film 121 may be a light-transmissive film.

Although it is illustrated in FIGS. 2A to 2C that the base film 121, the adhesive layer 123, and the unevenness covering layer 125 are concurrently formed in this order, it is not required for the base film 121, the adhesive layer 123, and the unevenness covering layer 125 to be formed concurrently.

In an exemplary embodiment, the base film 121, the adhesive layer 123, and the unevenness covering layer 125 may be formed one after another in this stated order on the active surface 111_1 of the processing target substrate 110. The base film 121, the adhesive layer 123, and the unevenness covering layer 125 may be sequentially formed by using various methods such as spin coating, doctor blading, dip coating, and spraying.

Referring to FIGS. 1 and 2D, an electrostatic carrier 130 contacts the planarization film 120 (S120). For example, the electrostatic carrier 130 may be disposed on the planarization film 120.

As described with reference to FIGS. 2A to 2C, unevenness of the active surface 111_1, such as that from the conductive bumps 114, is absorbed by the unevenness covering layer 125. Thus, a second surface 120_2, which is a free surface of the base film 121, has a substantially flat surface. If the second surface 120_2 of the base film 121 is not substantially flat, it may be difficult to fix the processing target substrate 110 to the electrostatic carrier 130. This is because adhesion between the electrostatic carrier 130 and the processing target substrate 110 may be insufficient due to the unevenness of the active surface 111_1.

The electrostatic carrier 130 may include a power supply unit 133 for supplying power and a switch 135 for controlling the supply of power. The power supply unit 133 and the switch 135 may be configured to supply power to an electrostatic chuck 131 when the switch 135 is closed.

Referring to FIGS. 1 and 2E, the processing target substrate 110 may be fixed to the electrostatic carrier 130 by supplying power to the electrostatic carrier 130 (S130).

When the switch 135 of the electrostatic carrier 130 is closed, power is supplied from the power supply unit 133 to generate electrostatic force in the electrostatic chuck 131, and then the processing target substrate 110 may be fixed thereto by the electrostatic force. For example, the processing target substrate 110 may be fixed to the electrostatic chuck 131 with the planarization film 120 interposed therebetween.

Then, after the processing target substrate 110 is fixed to the electrostatic chuck 131, a process for the processing target substrate 110 may be performed (S140). The process may include, for example, various processes such as thinning, molding, deposition, plating, and coating, but the inventive concept is not limited thereto. Although a thinning process is described with reference to FIG. 2E, one of ordinary skill in the art would be able to apply the method used in the thinning process to other processes.

As illustrated in FIG. 2E, the semiconductor substrate 111 may be polished from the opposite surface 111_2 until the penetration electrodes 112 are exposed. A polishing method such as an etch back method or chemical mechanical polishing (CMP) may be used to polish the opposite surface 111_2, but the inventive concept is not limited thereto.

Next, a conductive pad 116 may be formed on each of the exposed penetration electrodes 112. The conductive pad 116 may be formed by using a method such as electroplating, electroless plating, physical vapor deposition, chemical vapor deposition, or atomic layer deposition, but the method is not limited thereto.

Referring to FIGS. 1 and 2F, power supplied to the electrostatic carrier 130 is turned off and then the processing target substrate 110 may be separated from the electrostatic carrier 130 (S150).

For example, if the power supplied to the electrostatic chuck 131 is turned off, electrostatic force generated in the electrostatic chuck 131 disappears. Thus, the electrostatic chuck 131 and the processing target substrate 110 may be separated from each other. The power supplied to the electrostatic chuck 131 may be turned off by opening the switch 135.

Referring to FIGS. 1 and 2G, only the base film 121 may be removed from the processing target substrate 110 while leaving the unevenness covering layer 125 (S160). Here, in an exemplary embodiment, the adhesive layer 123 may also be removed from a surface of the processing target substrate 110 with the base film 121.

The base film 121 and the adhesive layer 123 may be removed from one side of the processing target substrate 110 by using a peel-off method. To peel off the base film 121 and the adhesive layer 123, a shock may be applied to a side surface of the base film 121 and/or the adhesive layer 123 by using a sharp tool to form a starting point for peeling.

Side surfaces of the conductive bump 114 are mostly protected by the unevenness covering layer 125, and the adhesive layer 123 that contacts some portions of an end portion of the conductive bump 114 is removed by the peel-off method. Thus, the peel-off method described above may not cause any physical damage to the conductive bump 114.

Referring to FIGS. 1 and 2H, the unevenness covering layer 125 may be removed from the processing target substrate 110 (S170). The unevenness covering layer 125 may be removed by, for example, a wet method. In other words, the unevenness covering layer 125 may be removed by using a solvent.

The solvent may be an organic solvent and include, for example, a chlorine-based solvent such as 1,2-dichloroethane, 1,1,2-trichloroethane chloro benzene and o-dichloro benzene, an ether-based solvent such as tetrahydrofuran, dioxane, anisole and 4-methyl anisole, an aromatic hydrocarbon-based solvent such as toluene, xylene, mesitylene, ethylbenzene, n-hexyl benzene and cyclohexyl benzene, an aliphatic hydrocarbon-based solvent such as cyclohexane, methyl cyclohexane, n-pentane, n-hexane, n-heptane, n-octane, n-nonane, n-decane, n-dodecane and bicyclohexane, a ketone-based solvent such as acetone, methylethyl ketone, cyclohexanone and acetophenone, an ester-based solvent such as ethyl acetate, butyl acetate, ethyl cellosolve acetate, methyl benzoate and phenyl acetate, a polyhydric alcohol-based solvent such as ethylene glycol, glycerin and 1,2-hexanediol, an alcohol-based solvent such as isopropyl alcohol and cyclohexanol, a sulfoxide-based solvent such as dimethylsulfoxide, and/or an amide-based solvent such as N-methyl-2-pyrrolidone and N, N-dimethylformamide. These solvents may be used alone or may be used as a combination of two or more solvents.

However, a method of removing the unevenness covering layer 125 from the processing target substrate 110 is not limited to a wet method. The unevenness covering layer 125 may be removed from the processing target substrate 110 by using a method such as an etch-back method or ashing.

The method of processing a substrate according to the inventive concept may have an effect such that the substrate may be quickly treated at a room temperature without imparting thermal/mechanical stress to the substrate.

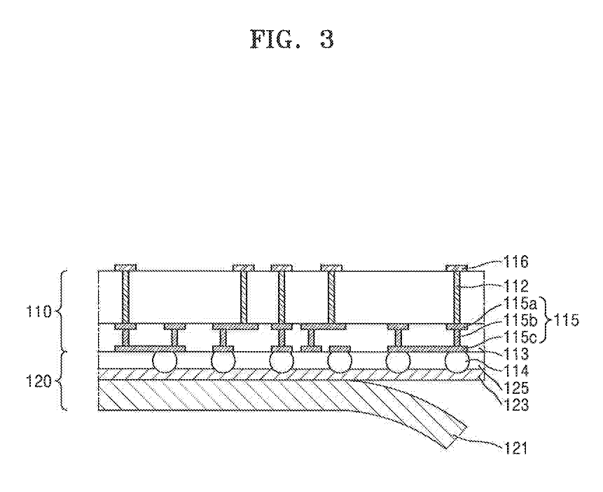

FIG. 3 illustrates a cross-sectional side view showing a method of removing the base film 121 from the processing target substrate 110, according to an exemplary embodiment of the inventive concept.

Descriptions provided with reference to FIG. 3 may correspond to descriptions of the aforementioned embodiment made with reference to FIG. 2G. In other words, descriptions up to FIG. 2F are common to the aforementioned embodiment and the present embodiment, and thus repeated descriptions may be omitted.

Referring to FIG. 3, the base film 121 may be removed from the processing target substrate 110 while leaving the adhesive layer 123 and the unevenness covering layer 125.

By varying the composition of the adhesive layer 123, relative adhesion thereof may be adjusted. In other words, the adhesion of the adhesive layer 123 with respect to the base film 121 and the adhesion of the adhesive layer 123 with respect to the unevenness covering layer 125 may be adjusted by varying the composition of the adhesive layer 123. For example, it is possible to adjust the adhesive force of the adhesive layer 123 by varying the ratio of the alkyl group, the alkenyl group, the aryl group, and the halogenated alkyl group from among the siloxane units constituting the silicone resin in the adhesive layer 123

Then, as illustrated in FIG. 2H, the adhesive layer 123 and the unevenness covering layer 125 may be removed from the processing target substrate 110. The adhesive layer 123 and the unevenness covering layer 125 may be removed by, for example, a wet method. In other words, the adhesive layer 123 and the unevenness covering layer 125 may be removed by a solvent. The solvent is described in the aforementioned embodiments, and thus, a repeated description thereof may be omitted herein.

Furthermore, in an exemplary embodiment of the inventive concept, the adhesive layer 123 and the unevenness covering layer 125 may be removed from the processing target substrate 110 by using a method such as an etch-back method or ashing.

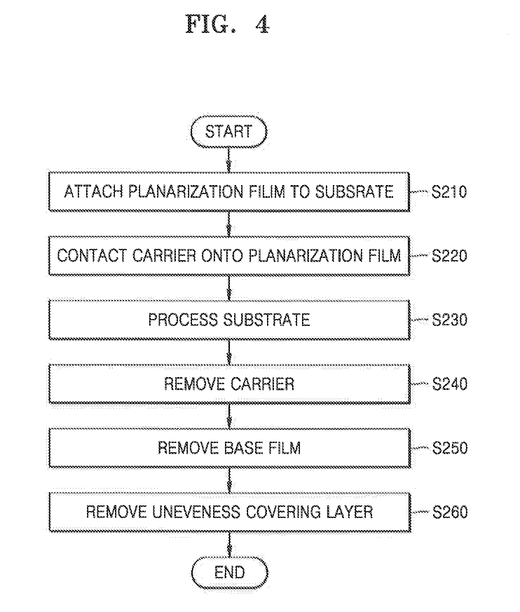

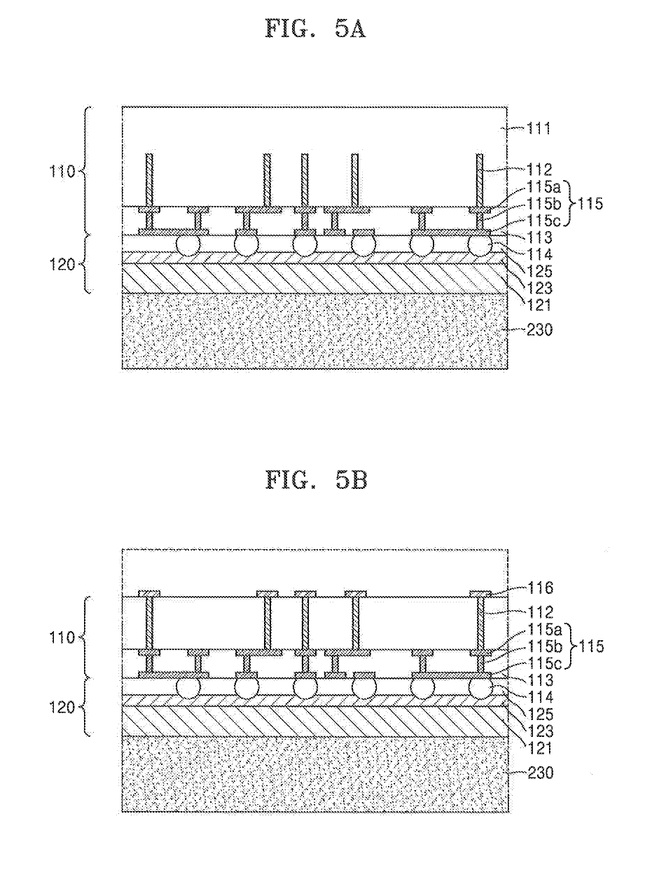

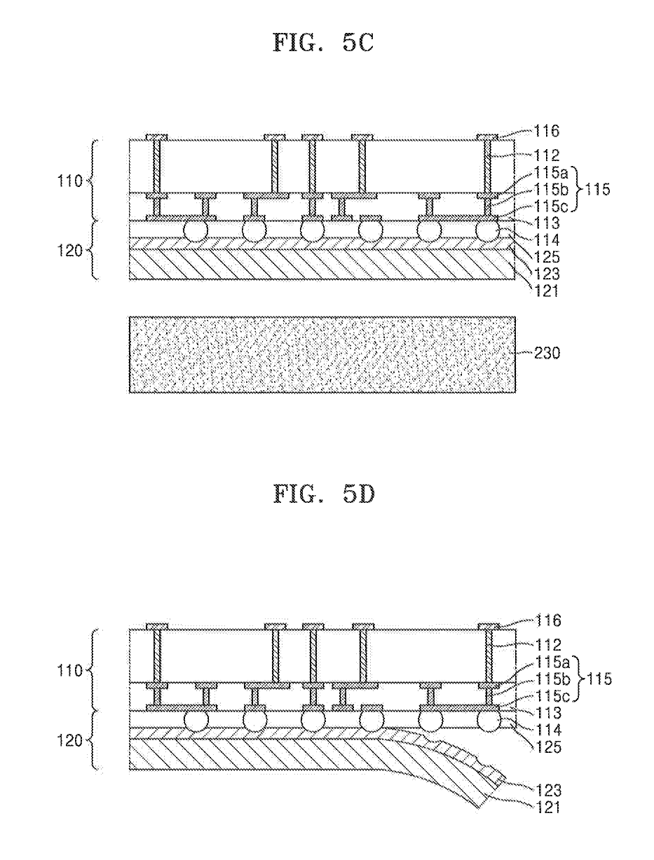

FIG. 4 illustrates a flowchart showing a method of processing a substrate, according to an exemplary embodiment of the inventive concept. FIGS. 5A to 5D illustrate cross-sectional side views showing side surfaces of a substrate, according to some steps of the processing method.

Referring to FIGS. 4 and 2C, the planarization film 120 is attached to the processing target substrate 110 (S210). The method of attaching the planarization film 120 to the processing target substrate 110 was described with reference to FIG. 1 and FIGS. 2A to 2C, and thus repeated descriptions thereof may be omitted herein.

Referring to FIGS. 4 and 5A, a carrier 230 is attached onto the planarization film 120 (S220). The carrier 230 may include, for example, silicon (e.g., blank device wafer), soda lime glass, borosilicate glass, silicon carbide, silicon germanium, silicon nitride, gallium arsenic, sapphire, various metals, and ceramics. However, the inventive concept is not limited thereto.

The carrier 230 may have sufficient thickness and strength to support the processing target substrate 110 while the processing target substrate 110 is handled and thinned.

The planarization film 120 may be attached to the carrier 230 by using various methods. In an exemplary embodiment, the planarization film 120 may be coupled to the carrier 230 by van der Waals forces between two surfaces contacting each other. In an exemplary embodiment, the planarization film 120 and the carrier 230 may be coupled to each other by an adhesive, for example, a silicone-based adhesive.

A plurality of conductive bumps 114 formed on a surface of the processing target substrate 110 may cause the surface to be uneven, and thus, an adhesive layer of considerable thickness may be required to bond the surface directly to the carrier 230. In addition, in an exemplary embodiment of FIG. 5A, the unevenness covering layer 125 substantially absorbs the unevenness caused by the conductive bumps 114, and the base film 121 may have a substantially flat lower surface. Therefore, the carrier 230 may be attached to the planarization film 120 with considerable bonding force.

Referring to FIGS. 4 and 5B, a process may be performed with respect to the processing target substrate 110 (S230). The process may be various processes such as thinning, molding, deposition, plating, and coating, but the inventive concept is not limited thereto. The thinning process is only described with reference to FIG. 5B, but one of ordinary skill in the art would be able to apply the method used for thinning to other processes. The thinning method is described with reference to FIG. 2E, and thus, a repeated description thereof may be omitted. Also, the formation of the conductive pads 116 on the penetration electrodes 112 exposed by thinning is described with reference FIG. 2E, and thus, a repeated description thereof may be omitted.

Referring to FIGS. 4 and 5C, the carrier 230 may be removed from the processing target substrate 110 and the planarization film 120 (S240). To remove the carrier 230, a shock may be applied to a side surface of the carrier 230 by using a sharp tool, to thereby form a starting point for peeling off.

Referring to FIGS. 4 and 5D, the base film 121 may be removed from the processing target substrate 110 while leaving the unevenness covering layer 125 (S250). Here, in an exemplary embodiment, the adhesive layer 123 may be removed from the surface of the processing target substrate 110 with the base film 121.

Although it is illustrated in FIGS. 5C and 5D that the carrier 230 is first removed and then the base film 121 is removed, one of ordinary skill in the art would understand that it is possible to simultaneously remove the carrier 230 and the base film 121.

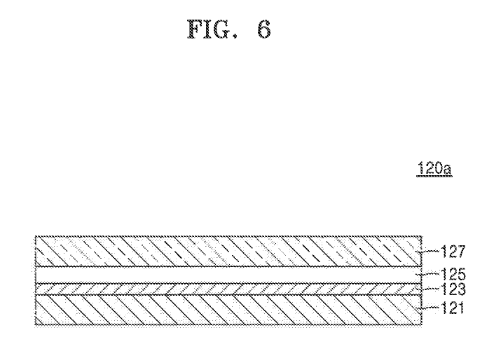

FIG. 6 illustrates a conceptual view showing a cross-section of a planarization film 120a according to an exemplary embodiment of the inventive concept.

Referring to FIG. 6, the base film 121, the adhesive layer 123, and the unevenness covering layer 125 are sequentially stacked, and a protective film layer 127 is provided on the unevenness covering layer 125.

The base film 121, the adhesive layer 123, and the unevenness covering layer 125 are described above in detail, and thus repeated descriptions thereof may be omitted herein.

The protective film layer 127 may be formed of polyimide, polyethylene terephthalate (PET), polyethylene, polypropylene, polyethylene-2,6-naphthalate, polypropylene terephthalate, polyamide-imide, polyethersulfone, polyether ether ketone, polycarbonate, polyarylate, cellulose propionate, polyvinyl chloride, polyvinylidene chloride, polyvinyl alcohol, polyether imide, polyphenylene sulfide, polyphenylene oxide, and/or polystyrene, but the inventive concept is not limited thereto.

Adhesive components may be interposed between the protective film layer 127 and the unevenness covering layer 125, but sufficient adhesion may be exerted by van der Waals force between the protective film layer 127 and the unevenness covering layer 125 without the adhesive component(s). In this case, the protective film layer 127 may directly contact the unevenness covering layer 125.

In this regard, if the protective film layer 127 is additionally provided, the planarization film 120a may be handled or distributed more conveniently.

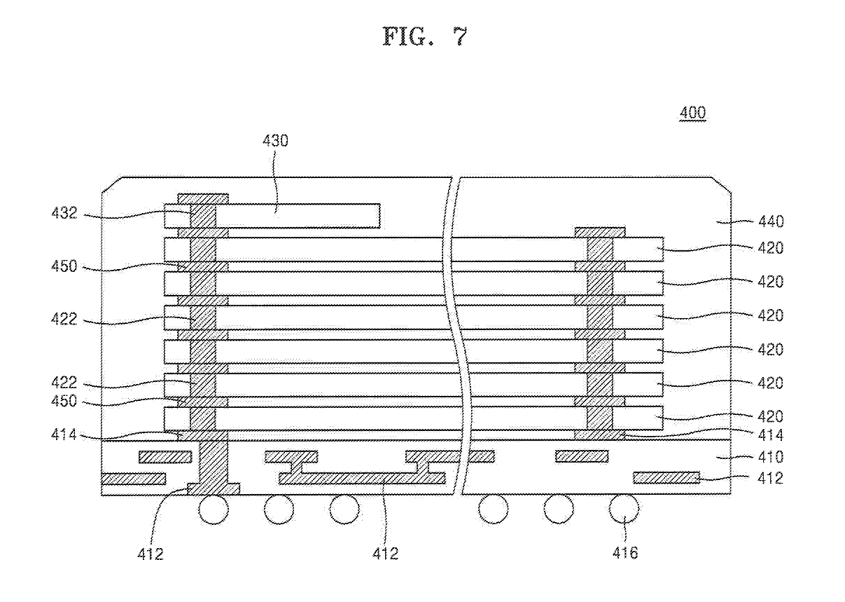

FIG. 7 illustrates a cross-sectional side view of a semiconductor package 400 manufactured using a processed substrate, according to an exemplary embodiment of the inventive concept.

Referring to FIG. 7, the processing target substrate 110 manufactured as described above is diced to obtain individual semiconductor chips 420, and the semiconductor package 400 may be manufactured using the semiconductor chips 420.

The semiconductor package 400 may include the plurality of semiconductor chips 420 sequentially stacked on a package substrate 410. A control chip 430 is connected to the semiconductor chips 420. A laminated structure of the semiconductor chips 420 and the control chip 430 is sealed with an encapsulant 440, such as a thermosetting resin, on the package substrate 410. Although FIG. 7 illustrates a structure in which six semiconductor chips 420 are vertically stacked, the number and the stacking direction of the semiconductor chips 420 is not limited thereto. The number of the semiconductor chips 420 may be determined to be less or greater than six as needed. The semiconductor chips 420 may be arranged horizontally on the package substrate 410 or arranged in a connection structure in which vertical mounting and horizontal mounting are combined. In an exemplary embodiment, the control chip 430 may be omitted.

The package substrate 410 may be a flexible printed circuit board, a rigid printed circuit board, or a combination thereof. The package substrate 410 includes internal substrate wiring 412 and the connection terminal 414. The connection terminal 414 may be formed on a side of the package substrate 410. Solder balls 416 may be formed on another side of the package substrate 410. The connection terminal 414 may be electrically connected to the solder balls 416 through the internal substrate wiring 412. In an exemplary embodiment, the solder balls 416 may be replaced with conductive bumps or a lead grid array (LGA).

The semiconductor chips 420 and the control chip 430 may include penetration electrodes 422 and 432. Each of the penetration electrodes 422 and 432 may include a central wiring metal layer and a barrier metal layer surrounding the wiring metal layer.

The penetration electrodes 422 and 432 may be electrically connected to the connection terminal 414 of the package substrate 410 by a conductive member 450 such as a bump. In an exemplary embodiment, the control chip 430 may not include the penetration electrodes 432.

Each of the semiconductor chips 420 may include a system LSI, a flash memory, a DRAM, an SRAM, an EEPROM, a PRAM, an MRAM, or resistive random-access memory (RRAM). The control chip 430 may include a logic circuit such as a serializer/deserializer (SER/DES) circuit.

While the inventive concept has been particularly shown and described with reference to embodiments thereof, it will be understood that various changes in form and details may be made therein without departing from the spirit and scope of the following claims.

What is claimed is:

1. A method of processing a substrate, the method comprising:
attaching a first surface of a planarization film to a processing target substrate;
disposing an electrostatic carrier onto a second surface of the planarization film opposite the first surface of the planarization film;
fixing the processing target substrate to the electrostatic carrier by supplying power to the electrostatic carrier, and
performing processing on the processing target substrate;
wherein the planarization film comprises a base film, an adhesive layer formed on the base film, and an unevenness covering layer formed on the adhesive layer.

2. The method of claim 1, wherein the unevenness covering layer is an unreacted thermosetting resin.

3. The method of claim 1, wherein the unevenness covering layer is configured to be cured by heat or light.

4. The method of claim 1, wherein the unevenness covering layer is configured to be cured by light, and
the base film is a light-transmissive film.

5. The method of claim 1, wherein the adhesive layer is a silicone-based resin.

6. The method of claim 1, wherein the first surface of the planarization film is a surface of the unevenness covering layer, and
the second surface of the planarization film is a surface of the base film.

7. The method of claim 1, wherein when the first surface of the planarization film is attached to the processing target substrate, the second surface is flat.

8. The method of claim 1, wherein a surface of the processing target substrate attached to the first surface has an uneven portion, and
a thickness of the unevenness covering layer is about 60% to about 95% of a height of the uneven portion of the processing target substrate.

9. The method of claim 8, wherein when the attaching of the first surface of the planarization film to the processing target substrate is performed, the unevenness covering layer fills a space between protruding parts of the uneven portion.

10. The method of claim 9, wherein when the attaching of the first surface of the planarization film to the processing target substrate is performed, the protruding parts of the uneven portion at least partly contact the adhesive layer.

11. The method of claim 1, wherein the attaching of the first surface of the planarization film to the processing target substrate comprises:
disposing the first surface of the planarization film onto the processing target substrate; and
curing the adhesive layer and the unevenness covering layer, and
wherein the curing of the adhesive layer and the unevenness covering layer comprises heating the adhesive layer and the unevenness covering layer to a temperature of about 60° C. to about 200° C.

12. The method of claim 1, further comprising:
separating the electrostatic carrier from the processing target substrate by turning off power of the electrostatic carrier after the processing on the processing target substrate is performed;
removing the base film from the processing target substrate while leaving the unevenness covering layer; and
removing the unevenness covering layer.

13. The method of claim 12, wherein when the removing of the base film from the processing target substrate is performed, the adhesive layer is removed from the processing target substrate.

14. The method of claim 12, wherein when the removing of the base film from the processing target substrate is performed, the adhesive layer remains with the unevenness covering layer.

15. The method of claim 12, wherein the removing of the base film from the processing target substrate is performed by using a peel-off method in which the base film is peeled off from a side of the processing target substrate.

16. A method of processing a substrate, the method comprising:
forming, on a processing target substrate, an unevenness covering layer, an adhesive layer and a base film layer;
curing the unevenness covering layer and the adhesive layer,
disposing an electrostatic carrier onto the base film layer;
fixing the processing target substrate to the electrostatic carrier by supplying power to the electrostatic carrier, and
processing the processing target substrate.

17. The method of claim 16, wherein the forming of the unevenness covering layer, the adhesive layer and the base film layer comprises simultaneously forming the unevenness covering layer, the adhesive layer and the base film layer in an order of the unevenness covering layer, the adhesive layer and the base film layer from the processing target substrate.

18. The method of claim 16, wherein the forming of the unevenness covering layer, the adhesive layer and the base film layer comprises sequentially forming the unevenness covering layer, the adhesive layer and the base film layer.

19. A method of thinning a substrate, the method comprising:
attaching a first surface of a planarization film to a thinning target substrate;
attaching a carrier substrate onto a second surface of the planarization film opposite the first surface of the planarization film;
performing thinning on the thinning target substrate; and
removing the carrier substrate;
wherein the planarization film comprises a base film, an adhesive layer formed on the base film, and an unevenness covering layer formed on the adhesive layer.

20. The method of claim 19, further comprising:
while or after the removing of the carrier substrate is performed, removing the base film from the thinning target substrate while leaving the unevenness covering layer; and
removing the unevenness covering layer by using a wet method, after the removing of the base film from the thinning target substrate is performed.
